(19) United States
(12) Patent Application Publication
(10) Pub. No.: US 2026/0351943 A1
(43) Pub. Date: Nov. 5, 2026

(54) RACK BUSBAR

(71) Applicant: BIZLINK INTERNATIONAL CORP., New Taipei City (TW)

(72) Inventors: Chao WANG, New Taipei City (TW); Zengshi LAO, New Taipei City (TW); Haoran ZOU, New Taipei City (TW)

(21) Appl. No.: 19/661,688

(22) Filed: Apr. 29, 2026

(30) Foreign Application Priority Data
Apr. 30, 2025 (CN) 202510571457.6

(51) Int. Cl. H02G 5/04; H05K 7/14

(52) U.S. Cl. CPC H02G 5/04; H05K 7/1492

(57) ABSTRACT

The present disclosure provides a rack busbar, comprising a housing defining an installation slot. A first busbar and a second busbar are disposed in the installation slot and extend along the length direction. An insulation member is sandwiched between the first busbar and the second busbar in a width direction and extends along the length direction, wherein a top portion of the insulation member in a height direction defines a groove extending along the length direction.

### CROSS-REFERENCE TO RELATED APPLICATION

This application claims priority to China Application Serial Number 202510571457.6, filed Apr. 30, 2025, which is herein incorporated by reference in its entirety.

### BACKGROUND

### Field of Invention

The present disclosure relates to connector technology, and more particularly, to a rack busbar for power distribution.

### Description of Related Art

A rack busbar is a power distribution system designed for data center server racks, which typically complies with the Open Compute Project (OCP) specifications. The primary function of a rack busbar is to efficiently and safely transmit power from a power shelf or a Power Supply Unit (PSU) to various server nodes within a server rack through conductive components, such as copper bars.

However, when a conventional rack busbar is energized, a leakage current path, generally known as a creepage path, can form on the surface of the insulating materials located between the conductive components. If the creepage distance of this path is insufficient, surface flashover or electrical breakdown may easily occur under high voltage conditions. Such electrical failures can cause severe consequences; in minor cases, they may damage the rack busbar and disrupt data center operations, while in severe cases, they may pose significant safety hazards and cause casualties.

### SUMMARY

The present disclosure relates to a rack busbar, which is capable of extending a creepage path between busbars to reduce safety hazards.

The present disclosure provides a rack busbar, comprising a housing defining an installation slot. A first busbar and a second busbar are disposed in the installation slot and extend along a length direction. An insulation member is sandwiched between the first busbar and the second busbar in a width direction and extends along the length direction. A top portion of the insulation member in a height direction defines a groove extending along the length direction.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a schematic structural view of a rack busbar in accordance with an embodiment of the present disclosure;

FIG. 2 is a schematic structural view of a rack busbar in accordance with another embodiment of the present disclosure; and

FIG. 3 is an enlarged partial view of portion A shown in FIG. 2.

### DETAILED DESCRIPTION

The technical solutions in the embodiments of the present disclosure will be described clearly and completely below with reference to the accompanying drawings in the embodiments of the present disclosure. It is apparent that the described embodiments are only a portion of the embodiments of the present disclosure, rather than all of the embodiments. Based on the embodiments in the present disclosure, all other embodiments obtained by those of ordinary skill in the art without creative effort shall fall within the scope of protection of the present disclosure.

It should be noted that if directional indicators (such as up, down, left, right, front, back, etc.) are involved in the embodiments of the present disclosure, the directional indicators are only used to explain the relative positional relationship, movement, etc., between various components in a specific posture. If the specific posture changes, the directional indicators will change accordingly.

In addition, if descriptions involving "first," "second," etc., are involved in the embodiments of the present disclosure, the descriptions of "first," "second," etc., are for descriptive purposes only and should not be understood as indicating or implying their relative importance or implicitly indicating the number of indicated technical features. Thus, a feature defined by "first" or "second" may explicitly or implicitly include at least one such feature. Furthermore, if "and/or" appears in the text, its meaning includes three parallel solutions; taking "A and/or B" as an example, it includes solution A, solution B, or a solution where both A and B are satisfied simultaneously. In addition, the technical solutions between various embodiments can be combined with each other, provided that such combinations are based on what can be realized by those of ordinary skill in the art. When a combination of technical solutions is contradictory or impossible to achieve, such a combination should be considered non-existent and is not within the scope of protection claimed by the present disclosure.

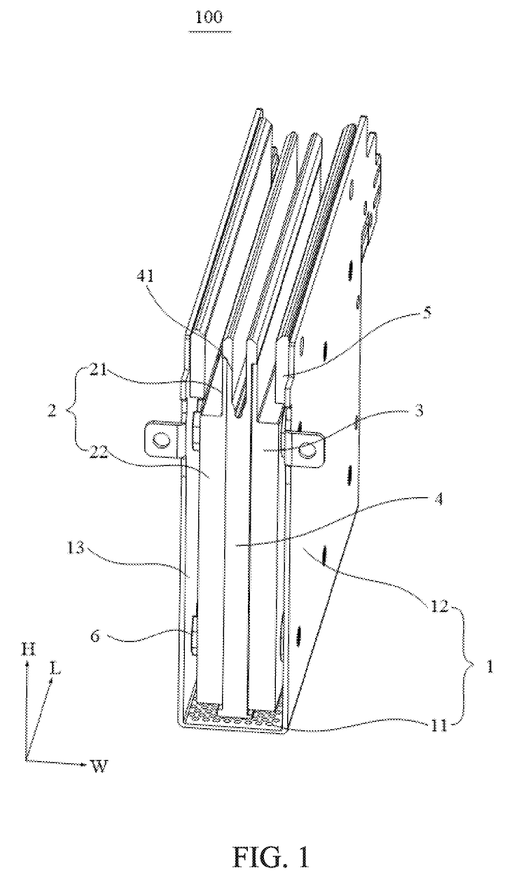

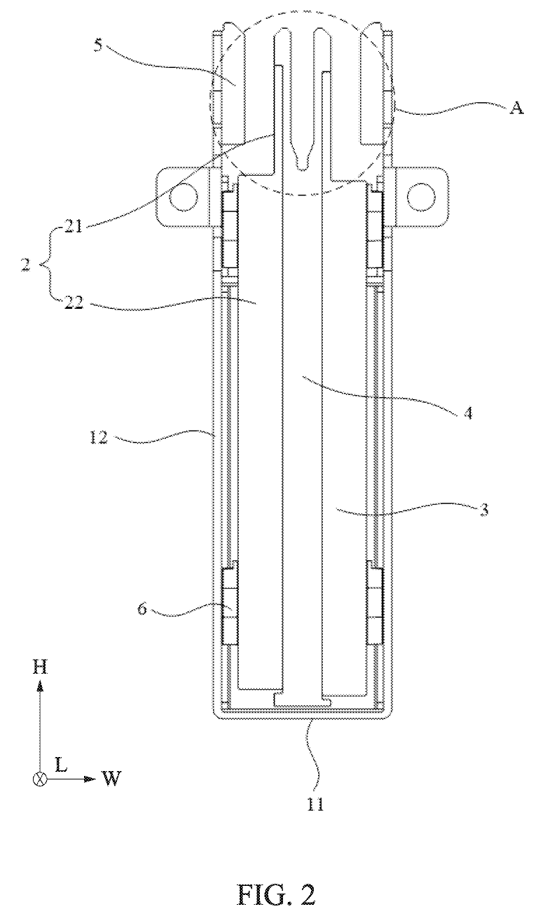

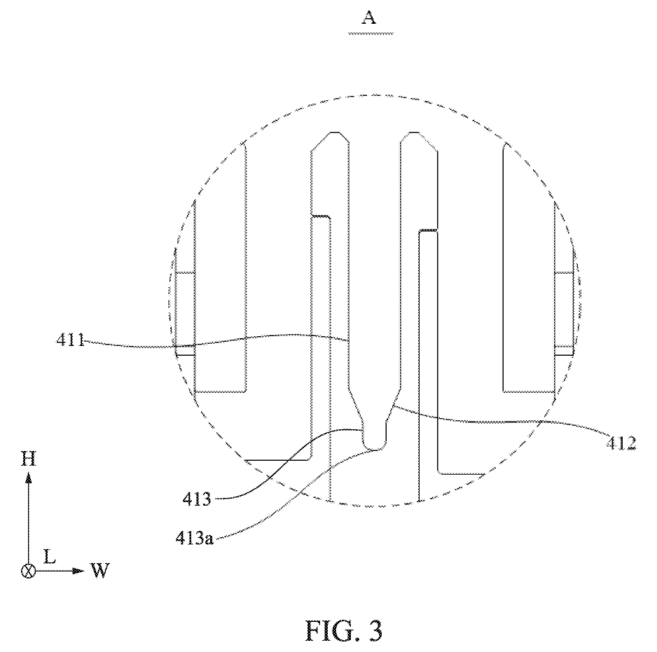

Referring to FIGS. 1-3, a rack busbar 100 in accordance with the present disclosure is provided. The rack busbar 100 is connected to a power source and transmit power to severs. The rack busbar 100 generally comprises a housing 1, a first busbar 2, a second busbar 3, and an insulation member 4. The insulation member 4 is a plate body. In some embodiments, the rack busbar 100 may further comprise two grounding bars 5 and a plurality of spacers 6.

Specifically, the housing 1 has a length direction L, a width direction W, and a height direction H. The housing 1 comprises a base plate 11 and two side plates 12. The two side plates 12 are connected to opposite sides of the base plate 11 and extend along the length direction L. Furthermore, the two side plates 12 and the base plate 11 enclose an installation slot 13. The installation slot 13 has an opening located opposite to the base plate 11 in the height direction H.

In an embodiment, the housing 1 is made of an insulating material, such as rigid plastic. In some embodiments, this configuration facilitates providing stable mechanical support for internal components disposed in the installation slot 13. Furthermore, the aforementioned material and structural design of the housing 1 facilitate effectively preventing external electrical leakage through the housing 1, thereby ensuring operational safety.

The first busbar 2 is disposed in the installation slot 13 and extends along the length direction L. Similarly, the second busbar 3 is disposed in the installation slot 13 and extends along the length direction L. Each of the first busbar 2 and the second busbar 3 comprises a head portion 21 and a shoulder portion 22. The head portion 21 of the first busbar 2 and the head portion 21 of the second busbar 3 are configured to mate and electrically connect with electrical connectors to supply power to various server nodes. The shoulder portion 22 refers to a laterally extending portion that contacts the side plate 12, extending laterally beyond the head portion 21 in the width direction W. Since the first busbar 2 and the second busbar 3 have the same dimensions, when the dimension of the housing 1 is fixed, a ratio of a width of the shoulder portion 22 to a perpendicular distance between the two side plates 12 is determined, which can be translated to determine the thickness of the insulation member 4. In an embodiment, during assembly, the ratio of the width of the shoulder portion 22 in the width direction W to the perpendicular distance between the two side plates 12 is in a range from 0.216 to 0.324. For instance, the ratio may be precisely 0.216, 0.24, 0.28, 0.324, or any value within the aforementioned range.

In an embodiment, the head portion 21 and the shoulder portion 22 are integrally formed. The integrally formed head portion 21 and shoulder portion 22 means that the main body structure of the busbar is formed into a seamless whole through continuous processing. Such a structure can be manufactured through a casting or stamping process.

In an embodiment, this configuration facilitates carrying a relatively larger current. Specifically, the shoulder portion 22 facilitates increasing a contact area with the side plate 12 to enhance structural stability. The integrally formed structure facilitates avoiding contact resistance commonly found at connecting joints of traditional split structures, thereby improving the current-carrying capacity. Furthermore, the specific width range of the shoulder portion 22 is configured to potentially balance performance and safety. If the width of the shoulder portion 22 is too low, it would be insufficient to carry a large current. Conversely, if the width of the shoulder portion 22 is too high, it would compress the insulation gap between the busbar and the side plate 12, thereby shortening the creepage path and easily causing surface flashover or electrical breakdown, which leads to safety hazards.

The materials and shapes of the first busbar 2 and the second busbar 3 may be common materials and shapes available in the market, which are not further limited herein. Furthermore, the housing 1, the first busbar 2, the second busbar 3, and the insulation member 4 are each provided with a plurality of connection holes. A plurality of connecting members respectively pass through the plurality of connection holes to connect these four components together as an integral unit.

The insulation member 4 is sandwiched between the first busbar 2 and the second busbar 3, and extends along the length direction L. The insulation member 4 comprises a top portion in the height direction H (i.e., the portion of the insulation member 4 facing away from the base plate 11 in the height direction H). The top portion of the insulation member 4 defines a groove 41, and the groove 41 extends along the length direction L. A depth of the groove 41 refers to a perpendicular distance from a top of the insulation member 4 to a bottom 41a of the groove 41 in the height direction H (i.e., a maximum dimension of the recessed structure in a direction perpendicular to the base plate 11). A height of the insulation member 4 refers to a total dimension of the insulation member 4 in the direction perpendicular to the base plate 11. In an embodiment, the depth of the groove 41 is in a range from 27.16 mm to 40.74 mm. For instance, the depth of the groove 41 may be 27.16 mm, 30 mm, 35 mm, 40.74 mm, or any value within the aforementioned range. Additionally, a ratio of the depth of the groove 41 to the height of the insulation member 4 is in a range from 0.16 to 0.24. For instance, the ratio may be precisely 0.16, 0.2, 0.24, or any value within the aforementioned range.

In an embodiment, the insulation member 4 is made of an insulating material, such as rubber, to insulate and separate the first busbar 2 from the second busbar 3. In some embodiments, this configuration facilitates extending a surface leakage current path (i.e., a creepage path) between a top portion of the first busbar 2 and a top portion of the second busbar 3. Setting the depth of the groove 41 within the specific range is configured to potentially ensure optimal performance. If the depth of the groove 41 is too small, the length of the creepage path would be insufficient to withstand a sufficient voltage, making it prone to breakdown or flashover. Conversely, if the depth of the groove 41 is too large, the structural strength of the insulation member 4 would decrease, and it would easily deform when a plug is inserted, causing the insulation function of the insulation member 4 to fail. Furthermore, the specific ratio between the depth and the height facilitates ensuring the formation of a sufficient creepage gap while preserving enough support thickness for the insulation member 4 to withstand busbar installation pressure, thereby preventing insulation failure.

In a cross section defined by the width direction W and the height direction H, the groove 41 has a tapered shape. Specifically, the groove 41 comprises a first portion 411, a second portion 412, and a third portion 413. The first portion 411 (which is an example of a first groove), the second portion 412 (which is an example of a second groove), and the third portion 413 (which is an example of a third groove) extend along the length direction L and sequentially communicate with each other along the height direction H. At least one of the first portion 411, the second portion 412, and the third portion 413 has a width in the width direction W different from an adjacent portion to define a non-uniform inner wall profile of the groove 41. In the cross section, the first portion 411 has a rectangular shape, the second portion 412 has a trapezoidal shape, and the third portion 413 has a curved shape. Corresponding to the non-uniform inner wall profile of the groove 41, solid portions of the insulation member 4 on opposite sides of the groove 41 exhibit specific thickness variations in the width direction W along the height direction H. Specifically, adjacent to the first portion 411, a thickness of the solid portions of the insulation member 4 remains constant. Adjacent to the second portion 412, as the width of the groove 41 decreases downwardly, the thickness of the solid portions of the insulation member 4 gradually increases from top to bottom. Adjacent to the third portion 413, the thickness of the solid portions of the insulation member 4 further increases along a curve to reach a maximum thickness at the bottom 41a of the groove 41.

Furthermore, the bottom 41a of the groove 41 is positioned at least equal to or higher than the shoulder portion 22 of the first busbar 2 and the shoulder portion 22 of the second busbar 3 in the height direction H.

Specifically, in order to preserve enough support thickness for the insulation member 4 and ensure mechanical stability to withstand busbar installation pressure, the bottom 41a of the groove 41 is positioned higher than the shoulder portion 22. The configuration means that a lowest point of the groove 41 of the insulation member 4 has a height difference in the height direction H relative to a top surface of the shoulder portion 22 of the first busbar 2 and the second busbar 3.

In an embodiment, the tapered shape of the groove 41 may alternatively be an inverted triangle. The first portion 411 refers to a rectangular cross-section groove continuously formed at the top portion of the insulation member 4 along the length direction L, which can be achieved through an injection molding process. The second portion 412 refers to a trapezoidal cross-section groove continuing to extend downward from a bottom of the first portion 411, which can be formed through mold processing. In another embodiment, the groove 41 may comprise only the first portion 411 and the second portion 412 communicating with each other in the height direction H. In this embodiment, the first portion 411 has a rectangular cross-sectional shape, and the second portion 412 has a triangular cross-sectional shape, wherein an apex of the triangular second portion 412 faces away from the top portion of the insulation member 4. It should be understood that, in other embodiments, the cross-sectional shape of the first portion 411 may also be a trapezoidal shape, and the cross-sectional shape of the second portion 412 may also be a rectangular shape, a triangular shape, or a curved shape.

In some embodiments, this configuration facilitates forming a three-stage composite structure at the top portion of the insulation member 4. By including multiple communicating portions, the groove 41 is configured to potentially have a larger depth to further extend the creepage path and reduce safety hazards. Specifically, the first portion 411 facilitates forming an initial creepage isolation space, and the second portion 412 is configured to potentially further extend the creepage path. When current passes through the busbars, the tapered shape and the stepped non-uniform profile of the groove 41 form a meandering current path on the surface of the insulation member 4, which facilitates preventing surface flashover by increasing the effective creepage distance.

Moreover, the curved edge design of the third portion 413 is configured to potentially optimize electric field distribution and smoothly disperse electrical stress along the curved surface, thereby avoiding field strength concentration at sharp corners. Additionally, maintaining the lowest point of the groove 41 higher than the top surface of the shoulder portion 22 facilitates preserving enough support thickness for the insulation member 4 to ensure its mechanical stability against busbar installation pressure, thereby preventing insulation failure.

The rack busbar 100 further comprises two grounding bars 5. The two grounding bars 5 are conductive components used to establish a reliable grounding path. Each of the grounding bars 5 is disposed on a respective one of the side plates 12 and located adjacent to an opening of the installation slot 13. The two grounding bars 5 are symmetrically arranged on outer edges of the two side plates 12 to form dual grounding protection.

Furthermore, the rack busbar 100 comprises a plurality of spacers 6. Some of the plurality of spacers 6 are spaced apart and sandwiched between the first busbar 2 and one of the side plates 12, and the others of the plurality of spacers 6 are spaced apart and sandwiched between the second busbar 3 and another one of the side plates 12. The spacers 6 are insulating support members used for filling a gap between the busbars and the side plates 12. Furthermore, the spacers 6 are configured to cooperate with a plurality of fasteners. The fasteners pass through the housing 1, the first busbar 2, the second busbar 3, the insulation member 4, and the spacers 6 to securely fix these components together as an integral unit. The spacers 6 are distributed in a non-continuous manner in contact areas between the busbars and the side plates 12. For example, one spacer 6 is provided at every certain interval.

A thickness of each of the plurality of spacers 6 in the width direction W refers to a dimension of the spacer 6 that extends between the side plate 12 and the corresponding busbar to maintain a physical gap therebetween. In an embodiment, the thickness of each of the plurality of spacers 6 in the width direction W is in a range from 3.2 mm to 4.8 mm. For instance, the thickness may be 3.2 mm, 3.6 mm, 4.0 mm, 4.4 mm, 4.8 mm, or any value within the aforementioned range. Additionally, a ratio of the thickness of each of the plurality of spacers 6 in the width direction W to a perpendicular distance between the two side plates 12 is in a range from 0.08 to 0.12. For instance, the ratio may be precisely 0.08, 0.1, 0.12, or any value within the aforementioned range.

In an embodiment, the grounding bars 5 may be implemented using copper strips or tin-plated copper bars. The grounding bars 5 are connected to the side plates 12 through mechanical fixation to form an electrical connection with an external grounding system. In an embodiment, the spacers 6 may be made of silicone, rubber, or polycarbonate formed by an injection molding process.

In some embodiments, this configuration facilitates several beneficial technical effects. The two symmetrically arranged grounding bars 5 are configured to potentially form the shortest connection path with external grounding terminals, capable of quickly directing abnormal charges to the ground and effectively eliminating the risk of leakage current accumulation. Meanwhile, a creepage path may also be formed between the shoulder portion 22 of the first busbar 2 (or the second busbar 3) and the corresponding grounding bar 5. The spaced arrangement of the multiple spacers 6 is intended to facilitate avoiding the formation of a continuous creepage path on a continuous contact surface, while preventing fasteners from deforming the housing 1 or the busbars, thereby ensuring stable installation.

Furthermore, the specific thickness and ratio of the spacers 6 are configured to potentially balance structural integrity and safety. The spacers 6 facilitate adjusting a length of the creepage path between the shoulder portion 22 and the corresponding grounding bar 5. If the thickness or its ratio is too large, the spacers 6 would occupy too much space in the installation slot 13, causing the thickness of the first busbar 2, the second busbar 3, or the insulation member 4 to be reduced. This could result in an inability of the electrical connector to carry a large current, or it could affect the width of the groove 41, thereby shortening the creepage path and easily causing surface flashover or electrical breakdown. Conversely, if the thickness or its ratio is too small, the creepage path between the shoulder portion 22 and the corresponding grounding bar 5 would become too short, also making it prone to surface flashover or electrical breakdown, which leads to safety hazards.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A rack busbar, comprising:
a housing defining an installation slot;
a first busbar and a second busbar disposed in the installation slot and extending along a length direction; and
an insulation member sandwiched between the first busbar and the second busbar in a width direction and extending along the length direction,
wherein a top portion of the insulation member in a height direction defines a groove extending along the length direction.

2. The rack busbar of claim 1, wherein each of the first busbar and the second busbar comprises a head portion and a shoulder portion extending laterally beyond the head portion in a width direction, and
wherein a bottom of the groove is positioned above the shoulder portion of the first busbar and the shoulder portion of the second busbar in the height direction.

3. The rack busbar of claim 1, wherein the housing comprises a base plate and two side plates connected to opposite sides of the base plate and extending along the length direction, and the two side plates and the base plate enclose the installation slot.

4. The rack busbar of claim 3, wherein the top portion of the insulation member is located adjacent to an opening of the installation slot, the opening being opposite to the base plate.

5. The rack busbar of claim 1, wherein the groove has a tapered shape in a cross section defined by the width direction and the height direction.

6. The rack busbar of claim 5, wherein the groove comprises a first portion, a second portion, and a third portion sequentially communicating with each other along the height direction, and
wherein at least one of the first portion, the second portion, and the third portion has a width in the width direction different from an adjacent portion to define a non-uniform inner wall profile of the groove.

7. The rack busbar of claim 6, wherein in the cross section defined by the width direction and the height direction, the first portion has a rectangular shape, the second portion has a trapezoidal shape, and the third portion has a curved shape.

8. The rack busbar of claim 3, wherein each of the first busbar and the second busbar comprises a head portion and a shoulder portion extending laterally beyond the head portion in the width direction, and
wherein a ratio of a width of the shoulder portion of the first busbar in the width direction to a perpendicular distance between the two side plates is in a range from 0.216 to 0.324.

9. The rack busbar of claim 8, wherein the ratio of the width of the shoulder portion to the perpendicular distance between the two side plates is 0.216, 0.24, 0.28 or 0.324.

10. The rack busbar of claim 1, wherein a depth of the groove in the height direction is in a range from 27.16 mm to 40.74 mm.

11. The rack busbar of claim 10, wherein the depth of the groove in the height direction is 27.16 mm, 30 mm, 35 mm, or 40.74 mm.

12. The rack busbar of claim 1, wherein a ratio of a depth of the groove in the height direction to a height of the insulation member in the height direction is in a range from 0.16 to 0.24.

13. The rack busbar of claim 12, wherein the ratio of the depth of the groove to the height of the insulation member is 0.16, 0.2, or 0.24.

14. The rack busbar of claim 4, further comprising:
two grounding bars, wherein each of the grounding bars is disposed on a respective one of the side plates and located adjacent to the opening of the installation slot.

15. The rack busbar of claim 3, further comprising:
a plurality of spacers, wherein some of the plurality of spacers are spaced apart and sandwiched between the first busbar and one of the side plates, and the others of the plurality of spacers are spaced apart sandwiched between the second busbar and another one of the side plates.

16. The rack busbar of claim 15, wherein the plurality of spacers are configured to cooperate with a plurality of fasteners to fix the housing, the first busbar, the second busbar, and the insulation member together.

17. The rack busbar of claim 15, wherein a thickness of each of the plurality of spacers in the width direction is in a range from 3.2 mm to 4.8 mm.

18. The rack busbar of claim 17, wherein the thickness of each of the plurality of spacers is 3.2 mm, 3.6 mm, 4.0 mm, 4.4 mm, or 4.8 mm.

19. The rack busbar of claim 15, wherein a ratio of a thickness of each of the plurality of spacers in the width direction to a perpendicular distance between the two side plates is in a range from 0.08 to 0.12.

20. The rack busbar of claim 19, wherein the ratio of the thickness to the perpendicular distance is 0.08, 0.1, or 0.12.
